(19) United States
(12) Patent Application Publication
(10) Pub. No.: US 2024/0356494 A1
(43) Pub. Date: Oct. 24, 2024

(54) SUPPLY MODULATING CIRCUIT AND COMMUNICATION CIRCUIT INCLUDING THE SAME

(71) Applicant: SAMSUNG ELECTRONICS CO., LTD., Suwon-si (KR)

(72) Inventors: Dongsu KIM, Suwon-si (KR); Junsuk Bang, Suwon-si (KR)

(73) Assignee: SAMSUNG ELECTRONICS CO., LTD., Suwon-si (KR)

(21) Appl. No.: 18/631,746

(22) Filed: Apr. 10, 2024

(30) Foreign Application Priority Data
Apr. 20, 2023 (KR) 10-2023-0052214
Jul. 5, 2023 (KR) 10-2023-0087406

(51) Int. Cl. H03F 1/02; H03F 3/24

(52) U.S. Cl. CPC H03F 1/0238; H03F 3/245; H03F 2200/451

(57) ABSTRACT

A communication circuit includes a first supply modulator configured to provide a first supply voltage; a second supply modulator configured to provide a second supply voltage; a switch configured to switch between output terminals of the first and second supply modulators; a first power amplifier configured to receive the first supply voltage and amplify a first input signal; a second power amplifier configured to receive the second supply voltage and amplify a second input signal; a third power amplifier configured to use third power higher than first power of the first power amplifier and second power of the second power amplifier, receive the first and second supply voltages, and amplify a third input signal; and a control circuit configured to control a switching operation of the switch based on an operation mode and activate at least one of the first to third power amplifiers based on the operation mode.

### CROSS-REFERENCE TO RELATED APPLICATION

This application is based on and claims priority under 35 U.S.C. § 119 to Korean Patent Application No. 10-2023-0052214, filed on Apr. 20, 2023, and Korean Patent Application No. 10-2023-0087406, filed on Jul. 5, 2023, in the Korean Intellectual Property Office, the disclosures of which are incorporated by reference herein in their entireties.

### BACKGROUND

The present disclosure relates to a communication circuit, and more particularly, to a supply modulating circuit configured through a switching operation and a communication circuit including the same.

For wireless communication, technologies, such as 2G, non-standard satellite communications, wideband code division multiple access (WCDMA) 3^{rd} generation (3G), long-term evolution (LTE), LTE Advanced (4G), and 5G have been used. With the recent development of communication technology, high peak-to-average ratio (PAPR) and high bandwidth of transmission/reception signals have been required. To improve power efficiency, chips supporting average power tracking and/or envelope tracking are referred to as supply modulators.

### SUMMARY

Embodiments provide a supply modulating circuit and a communication circuit including the same for more smoothly supplying power by configuring circuits more diversely and efficiently.

According to an aspect of an example embodiment, a communication circuit includes: a first supply modulator configured to provide a first supply voltage; a second supply modulator configured to provide a second supply voltage; a switch configured to switch between output terminals of the first supply modulator and the second supply modulator; a first power amplifier configured to receive the first supply voltage and amplify a first input signal; a second power amplifier configured to receive the second supply voltage and amplify a second input signal; a third power amplifier configured to use third power higher than first power of the first power amplifier and second power of the second power amplifier, receive the first supply voltage and the second supply voltage, and amplify a third input signal; and a control circuit configured to control a switching operation of the switch based on an operation mode and activate at least one of the first power amplifier, the second power amplifier, and the third power amplifier based on the operation mode.

According to an aspect of an example embodiment, a communication circuit includes: a first power amplifier circuit; a first supply modulator configured to provide a first supply voltage to the first power amplifier circuit; a second power amplifier circuit; a second supply modulator configured to provide a second supply voltage to the second power amplifier circuit; a third power; a first switch having one end connected to a first input terminal of the first power amplifier circuit and another end connected to a third input terminal of the third power amplifier circuit; a second switch having one end connected to a second input terminal of the second power amplifier circuit and another end connected to the third input terminal of the third power amplifier circuit; and a control circuit configured to control the first switch and the second switch upon receiving a control signal based on an operation mode, wherein the third input terminal of the third power amplifier circuit is connected to at least one of the first supply modulator and the second supply modulator.

According to an aspect of an example embodiment, a supply modulating circuit includes: a first supply modulator configured to output a first supply voltage through a first output terminal; a second supply modulator configured to output a second supply voltage through a second output terminal; a first switch having one end connected to the first output terminal and another end connected to a third output terminal, the first switch being configured to switch between the first output terminal and the third output terminal; and a second switch having one end connected to the second output terminal and another end connected to the third output terminal, the second switch being configured to switch between the first output terminal and the third output terminal.

### BRIEF DESCRIPTION OF THE DRAWINGS

The above and/or other aspect will be more clearly understood from the following detailed description taken in conjunction with the accompanying drawings, in which:

FIG. 1 is a block diagram schematically illustrating a wireless communication system according to one or more embodiments;

FIG. 2 is a block diagram illustrating a communication circuit according to one or more embodiments;

FIG. 3 is a circuit diagram illustrating a supply modulating circuit and a power amplifier according to one or more embodiments;

FIGS. 4A, 4B, and 5 are diagrams illustrating circuit operations according to operation modes of a supply modulating circuit and a power amplifier according to embodiments;

FIG. 6 is a circuit diagram illustrating a supply modulating circuit according to one or more embodiments;

FIG. 7 is a graph illustrating characteristics of current measured in the supply modulating circuit of FIG. 6;

FIG. 8 is a diagram illustrating a supply modulating circuit and a power amplifier circuit according to one or more embodiments;

FIGS. 9A to 9C are diagrams illustrating circuit operations according to operation modes of a supply modulating circuit and a power amplifier circuit according to embodiments;

FIG. 10 is a diagram illustrating a supply modulating circuit and a power amplifier circuit according to one or more embodiments;

FIGS. 11A and 11B are diagrams illustrating circuit operations according to operation modes of a supply modulating circuit and a power amplifier circuit according to embodiments; and

FIG. 12 is a circuit diagram illustrating a supply modulating circuit according to one or more embodiments.

### DETAILED DESCRIPTION

Hereinafter, embodiments are described in detail with reference to the accompanying drawings.

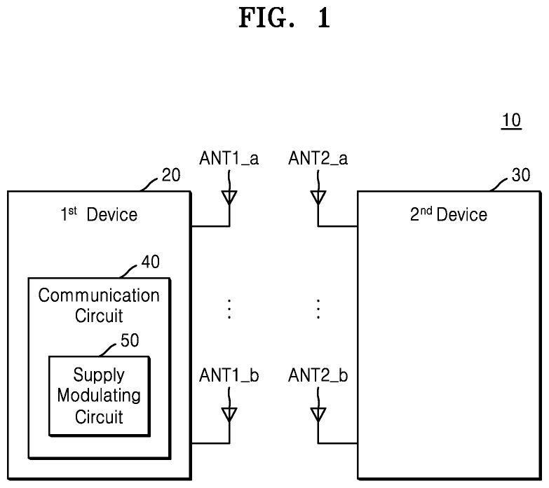

FIG. 1 is a block diagram schematically illustrating a wireless communication system 10 according to one or more embodiments.

Referring to FIG. 1, the wireless communication system 10 may include a first device 20 and a second device 30. The first device 20 may communicate with the second device 30 through a wireless communication function. The wireless communication system 10 may include a long-term evolution (LTE) system, an LTE-Advanced (LTE-A) system, a code division multiple access (CDMA) system, a global system for mobile communications (GSM) system, a wireless local area network (WLAN) system, a wireless fidelity (WiFi) system, a Bluetooth system, a Bluetooth low energy (BLE) system, a Zigbee system, a near field communication (NFC) system, a magnetic secure transmission system, a radio frequency (RF) system, or a body area network (BAN) system. However, the wireless communication system 10 is not limited to this embodiment and various communication systems may be configured.

The first device 20 and the second device 30 may refer to various devices capable of transmitting and receiving data and/or control information to and from each other through communication. As an example, the first device 20 and the second device 30 may be configured as one of user equipment (UE) and a base station (BS). The UE is a wireless communication device, which may be fixed or mobile, and may be referred to as terminal equipment, a mobile station (MS), a mobile terminal (MT), a user terminal (UT), a subscriber station (SS), a wireless device, a handheld device, and the like. The BS may generally refer to a fixed station that communicates with UE and/or other BSs and may also be referred to as a Node B, an evolved-Node B (eNB), a base transceiver system (BTS). As another example, the first device 20 and the second device 30 may be configured as one of a client and an access point (AP). The client may establish a communication connection with the AP based on WiFi communication.

Each of the first device 20 and the second device 30 may operate as one of a transmitting device and a receiving device depending on circumstances. When the first device 20 operates as a transmitting device, the second device 30 may operate as a receiving device, and when the second device 30 operates as a transmitting device, the first device 20 may operate as a receiving device.

The first device 20 may communicate with the second device 30 using a multiple input multiple output (MIMO) method. To perform this, the first device 20 and the in second device 30 may include a plurality of antennas ANT1_a and ANT1_b and ANT2_a and ANT2_b, respectively.

A communication network between the first device 20 and the second device 30 may share available network resources to support multiple users to communicate with each other. For example, in a wireless communication network, information may be transferred in various manners, such as CDMA, frequency division multiple access (FDMA), time division multiple access (TDMA), orthogonal frequency division multiple access (OFDMA), single carrier frequency division multiple access (SC-FDMA). In an example, as described above, the communication network may provide MIMO communication.

The first device 20 may include a communication circuit 40 for performing communication, and the communication circuit 40 may include a supply modulating circuit 50. When the first device 20 operates as a transmitter, the supply modulating circuit 50 may generate modulated voltages having levels that change dynamically based on an envelope signal and an interface signal and provide the generated modulated voltages, as supply voltages, to a power amplifier. As is described below, the supply modulating circuit 50 may provide various supply voltages to the power amplifier through a switching operation.

As is described in detail below, the supply modulating circuit 50 according to one or more embodiments may adjust a supply voltage in various manners through a switching operation according to an operation mode and may support various combinations of power modulation operations. Through this, the supply modulating circuit 50 according to one or more embodiments may obtain a high-capacity output through various combinations even with a low-capacity converter, and further reduce the cost and size of the circuit for power modulation.

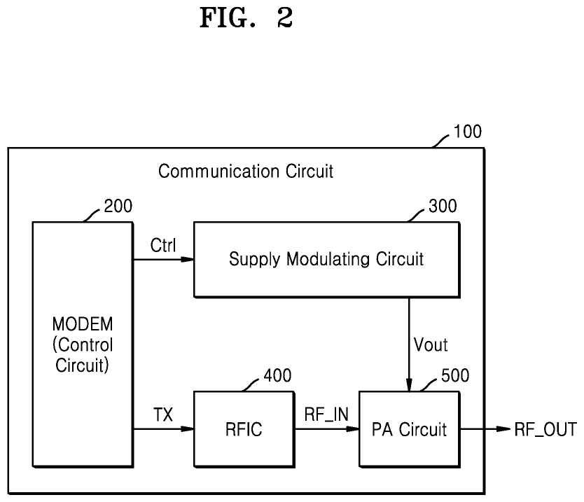

FIG. 2 is a block diagram illustrating a communication circuit 100 according to one or more embodiments.

Referring to FIG. 2, the communication circuit 100 may be mounted on a wireless communication device to transmit data to an external device. The communication circuit 100 may further include various components not shown in the drawing to transmit and receive data to and from the components. The communication circuit 100 may output a transmission signal through a plurality of frequency bands using carrier aggregation (CA). To this end, the communication circuit 100 may include a plurality of PAs for power amplifying a plurality of RF input signals respectively corresponding to a plurality of carriers.

In some embodiments, the communication circuit 100 may include a modem 200 (control circuit), a supply modulating circuit 300, a radio frequency integrated circuit (RFIC) 400, and a PA circuit 500. The PA circuit 500 may include a plurality of PAs respectively corresponding to a plurality of carriers.

The modem 200 may process a baseband signal including information to be transmitted according to various communication methods. For example, the modem 200 may process signals to be transmitted according to communication schemes, such as OFDM, OFDMA, wideband code multiple access (WCDMA), and high speed packet access+ (HSPA+). In addition, the modem 200 may process signals according to various types of communication methods to which a technique for modulating an amplitude and frequency of a transmission signal is applied.

The modem 200 may generate a transmission signal TX from a baseband signal including information to be transmitted through a carrier wave. In addition, the modem 200 may generate various control signals Ctrl to output signals for communication.

In some embodiments, the control signal Ctrl may include a signal for controlling an operation of the supply modulating circuit 300. As is described below, the supply modulating circuit 300 may provide various output voltages Vout through a switching operation according to an operation mode. Here, the modem 200 may control the supply modulating circuit 300 through the control signal Ctrl. For example, the modem 200 may output the corresponding control signal Ctrl based on the operation mode, and the supply modulating circuit 300 may adjust an output voltage of a supply modulator included in the supply modulating circuit 300 based on the control signal Ctrl. Also, the supply modulating circuit 300 may control a switch within the supply modulating circuit 300 based on the control signal Ctrl. However, embodiments are not limited to this drawing and may be implemented in various aspects. For example, a separate switch controller may be implemented to control the switch in the supply modulating circuit 300, or the above switch controller may be located in the supply modulating circuit 300 to perform a control operation.

In some embodiments, based on envelope detection in the baseband signal, the control signal Ctrl may include an envelope signal and an interface signal. In an embodiment, the interface signal may include an operating frequency signal and an average power signal, and the envelope signal and average power signal may correspond to an amplitude component of the transmission signal TX. The average power signal may be provided to the supply modulating circuit 300 as a reference voltage for each section. In this drawing, a single control signal Ctrl is shown as being output, but this is for convenience of description, and as described above, various signals for controlling the communication circuit 100 may be implemented in various manners, these signals may be collectively referred to as the control signal Ctrl. For example, a plurality of average power signals may be output in the form of serial data or parallel data, and a plurality of envelope signals may be generated. Also, in an embodiment, the transmission signal TX and the envelope signal may be differential signals including a positive signal and a negative signal, respectively.

The transmission signal TX and the envelope signal output from the modem 200 may be analog signals, and the average power signal may be a digital signal. The modem 200 may perform digital/analog conversion on a plurality of baseband signals and digital envelope signals for the plurality of baseband signals using a digital-to-analog converter (DAC) provided therein to generate a plurality of transmission signals TX and an envelope signal, which are analog signals. An average power signal output from the modem 200 may be converted into an analog signal, for example, a reference voltage, through a DAC provided in the supply modulating circuit 300. As an example, the DAC provided in the modem 200 may operate at a relatively higher speed than that of the DAC provided in the supply modulating circuit 300. However, without being limited thereto, the modem 200 may convert the average power signal into an analog signal and output the analog signal. The average power signal converted into an analog signal may be provided, as a reference voltage, to the supply modulating circuit 300.

An operating frequency signal output from the modem 200 may include information on an operating frequency used for wireless communication with a receiver. In a MIMO system, a wireless communication device may communicate with the receiver using a plurality of operating frequencies, and in this case, the operating frequency signal may include information on the operating frequencies. In this drawing, the operating frequency signal and the average power signal are shown in the form of being included in one control signal Ctrl, but this is only an example, and the operating frequency signal and the average power signal may be provided as separate signals to the supply modulating circuit 300 through different signal lines.

In some embodiments, the supply modulating circuit 300 may generate modulated voltages having levels that dynamically change based on the control signal Ctrl, may output various output voltages Vout through a switching operation based on the control signal Ctrl according to an operation mode, and provide the various output voltages Vout as supply voltages to the PA circuit 500. The supply modulating circuit 300 according to an embodiment may include supply modulators providing respective voltages, and variously combine voltages provided from the supply modulators according to operation modes through a switching operation to provide the output voltage Vout to the PAs.

The RFIC 400 may generate an RF input signal RF_IN by performing frequency up-conversion on the transmission signal TX based on a corresponding carrier wave.

The PA circuit 500 may include PAs and may generate an RF output signal RF_OUT by amplifying power of the RF input signal RF_IN. Each of the PAs may amplify power of the received RF input signal RF_IN based on the applied power voltage (e.g., the output voltage Vout provided from the supply modulating circuit 300).

In some embodiments, the PA circuit 500 may control whether each PA is activated based on an enable signal. When receiving an activated enable signal, the PA included in the PA circuit 500 may receive the output voltage Vout from the supply modulating circuit 300 and the RF input signal RF_IN from the RFIC 400, amplify the same, and then output the RF output signal RF_OUT. The enable signal may be output by the supply modulating circuit 300. In another example, the enable signal may be output by the modem 200 or the RFIC 400. The RF output signal RF_OUT may be transmitted through a corresponding antenna.

The supply modulating circuit 300 according to one or more embodiments may variously combine voltages respectively output from the supply modulators through a switching operation based on the control signal Ctrl according to an operation mode, and as an example, a high-capacity output may be provided to the PA even with a low-capacity converter. Therefore, the supply modulating circuit 300 according to the one or more embodiments may reduce the cost for power modulation and configure the circuit more efficiently.

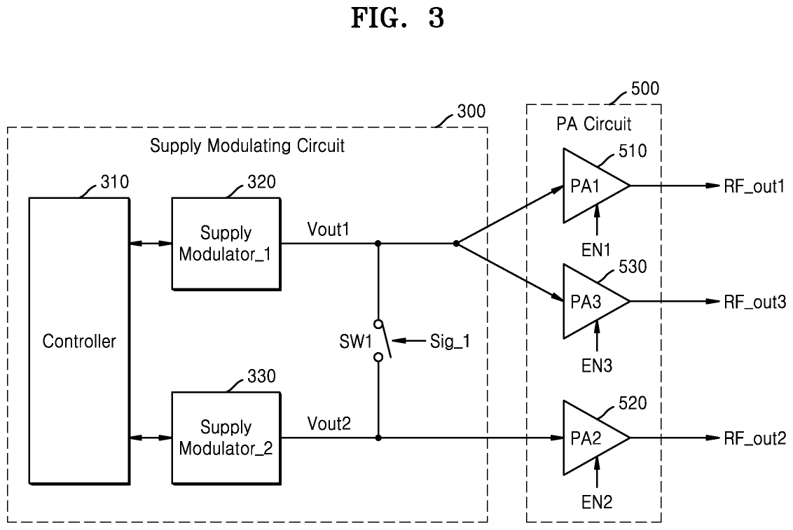

FIG. 3 is a circuit diagram illustrating the supply modulating circuit 300 and the PA circuit 500 according to an embodiment.

Referring to FIG. 3, the supply modulating circuit 300 may include a controller 310, a first supply modulator (or a supply modulator_1) 320, a second supply modulator (or a supply modulator_2) 330, and a first switch SW1, and the PA circuit 500 may include a first PA (PA1) 510, a second PA (PA2) 520 and a third PA (pa3) 530.

As described above with reference to FIG. 2, the supply modulating circuit 300 may operate based on the control signal Ctrl according to an operation mode. The controller 310 may control each of the first supply modulator 320 and the second supply modulator 330 based on the control signal Ctrl to adjust the output of each of a first voltage Vout1 and a second voltage Vout2. Also, the controller 310 may control a multi-phase operation between the first supply modulator 320 and the second supply modulator 330 as is described below.

The first supply modulator 320 and the second supply modulator 330 may respectively output the first voltage Vout1 and the second voltage Vout2 under control by the controller 310. In some embodiments, the first supply modulator 320 and/or the second supply modulator 330 may be modulators using a relatively small capacity converter (e.g., a DC-DC converter).

The first switch SW1 may perform a turn-on/turn-off operation based on a first switching signal Sig_1. A logic level of the first switching signal Sig_1 may be determined according to an operation mode. For example, the first switching signal Sig_1 may have a logic high or logic low voltage level, and accordingly, the first switch SW1 may be shorted or opened, respectively. As described above, the first switching signal Sig_1 may be provided from an external source, such as a modem or a control circuit, or may be provided from a separate switch controller for controlling a switch in the supply modulating circuit 300. The supply modulating circuit 300 may output the first and second voltages Vout1 and Vout2 in various combinations through a switching operation of the first switch SW1.

The PA circuit 500 may receive an output voltage from the supply modulating circuit 300 and perform an amplification operation. For example, the PA1 510 may receive the first enable signal EN1 based on an operation mode. When the PA1 510 is activated according to the first enable signal EN1, the PA1 510 may amplify the RF input signal based on a voltage provided from the supply modulating circuit 300 to generate a first RF output signal RF_out1. Similarly, when the PA2 520 is activated according to a second enable signal EN2, the PA2 520 may generate a second RF output signal RF_out2 based on the voltage provided from the supply modulating circuit 300. The PA3 530 may also be activated according to a third enable signal EN3 to generate a third RF output signal RF_out3 based on the voltage provided from the supply modulating circuit 300.

In some embodiments, required power of the PA1 510 and the PA2 520 may be relatively small, whereas required power of the PA3 520 may be relatively large. However, without being limited to this drawing, the arrangement of a low-capacity/high-capacity power amplifier may be variously implemented In an embodiment, in the PA circuit 500 corresponding to the second supply modulator 330, like the PA1 510 and the PA3 530 corresponding to the first supply modulator 320, a high-capacity PA may be additionally disposed in addition to the PA2 520.

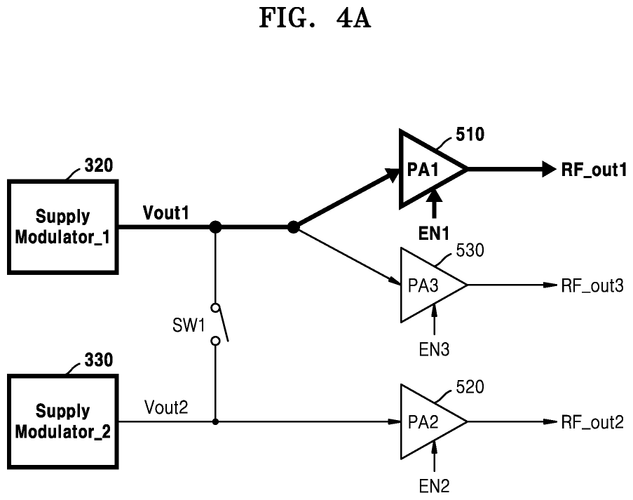

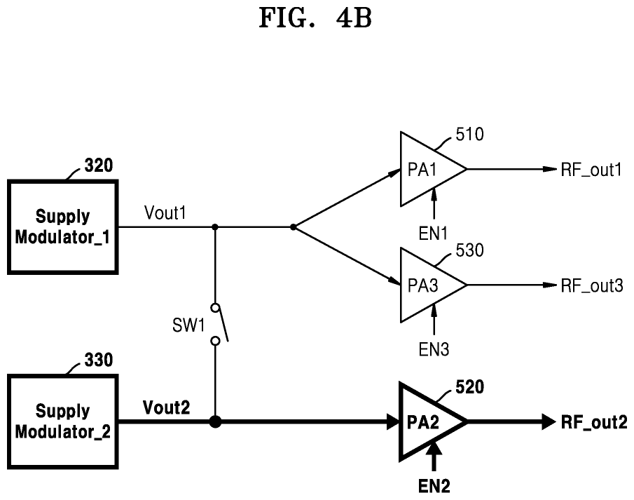

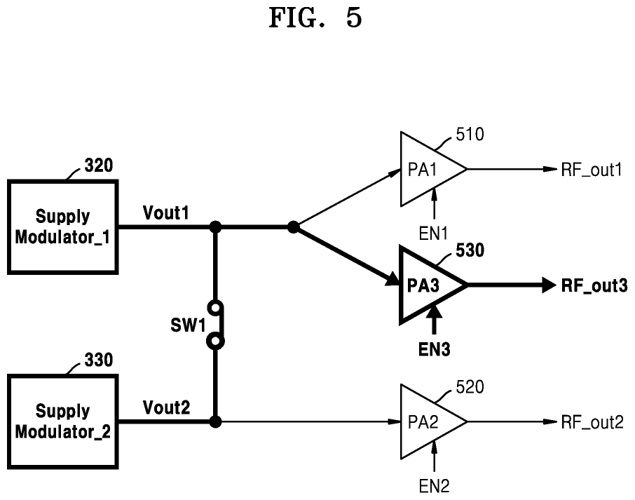

FIGS. 4A, 4B, and 5 are diagrams illustrating circuit operations of a supply modulating circuit and a power amplifier according to operation modes according to embodiments.

Referring to FIG. 4A, the supply modulating circuit 300 and the PA circuit 500 may operate according to a first operation mode. The first operation mode may be referred to as a low-capacity single output mode. As described above, the first and second supply modulators 320 and 330 may be modulators using relatively small capacitance converters, and required power of the PA1 510 and the PA2 520 may be relatively small.

In some embodiments, in the first operation mode, the first switch SW1 may be turned off and opened based on the aforementioned switching signal. The first voltage Vout1 output from the first supply modulator 320 may be applied to the PA1 510 and the PA3 520. In this case, in the first operation mode, the PA1 510, which is a low-capacity amplifier, may be activated based on the first enable signal EN1, and accordingly, the PA1 510 may output the first RF output signal RF_out1 based on the first voltage Vout1. The PA3 530 may be deactivated based on the third enable signal EN3 and may thus not operate even when the first voltage Vout1 is applied thereto (that is, the PA3 520 may be in a disable state). Similarly, the PA2 520 may be deactivated based on the second enable signal EN2 and may not operate. That is, in the first operation mode, only the PA1 510, which is a low-capacity power amplifier, may generate an RF output signal.

Referring to FIG. 4B, the supply modulating circuit 300 and the PA circuit 500 may operate in different combinations in the first operation mode, that is, a low-capacity single output mode.

In some embodiments, in the first operation mode, the first switch SW1 may be turned off and opened based on a switching signal. The second voltage Vout2 output from the second supply modulator 330 may be applied to the PA2 520. Here, in the first operation mode, the PA2 520, which is a low-capacity amplifier, may be activated based on the second enable signal EN2, and accordingly, the PA2 520 may output the second RF output signal RF_out2 based on the second voltage Vout2. The PA1 510 may be deactivated based on the first enable signal EN1 and may thus not operate even when the first voltage Vout1 is applied thereto (that is, the PA1 510 may be in a disable state). Similarly, the PA3 520 may be deactivated based on the third enable signal EN3 and may not operate. That is, in the first operation mode, only the PA2 520, which is a low-capacity power amplifier, may generate an RF output signal.

In some embodiments, the supply modulating circuit 300 and the PA circuit 500 may operate according to a second operation mode. The second operation mode may be referred to as a low-capacity simultaneous output mode. In the case of the second operation mode, as described above with reference to FIGS. 4A and 4B, the low-capacity PAs (i.e., the PA1 510 and the PA2 520), which operated alone, may all be activated to generate RF signals. In an embodiment, the first switch SW1 may be turned off and opened based on a switching signal. The first voltage Vout1 may be applied to the PA1 510 and PA3 530, and the second voltage Vout2 may be applied to the PA2 520. Here, in the second operation mode, both the PA1 510 and the PA2 520, which are low-capacity amplifiers, may be activated based on the first enable signal EN1 and the second enable signal EN2, and accordingly, the PA1 510 and the PA2 520 may output a first RF output signal RF_out1 and a second RF output signal RF_out2 based on the first voltage Vout1 and the second voltage Vout2, respectively. The PA3 520 may be deactivated based on the third enable signal EN3 and may not operate. That is, in the second operation mode, both the PA1 510 and PA2 520, which are low-capacity PAs, may generate RF output signals.

Referring to FIG. 5, the supply modulating circuit 300 and the PA circuit 500 may operate according to a third operation mode. The third operation mode may be referred to as a high-capacity output mode.

In some embodiments, in the case of the third operation mode, the first switch SW1 may be turned on and shorted based on the switching signal. Therefore, both the first voltage Vout1 and the second voltage Vout2 output from the first supply modulator 320 and the second supply modulator 330 may be applied to the PA3 520, which is a high-capacity power amplifier. Here, in the third operation mode, the PA3 520 may be activated based on the third enable signal EN3, and accordingly, the PA3 520 may generate the third RF output signal RF_out3 based on the first voltage Vout1 and the second voltage Vout2. The PA1 510 and the PA2 520 may be deactivated based on the first and second enable signals EN1 and EN2 and may thus not operate even when a voltage is applied thereto (that is, the PA1 510 and the PA2 520 may be in a disable state). That is, in the third operation mode, only the PA3 520, which is a high-capacity power amplifier, may generate an RF output signal.

That is, the supply modulating circuit according to one or more embodiments may adjust the supply voltage and the port from which the voltage is output in various manners through a switching operation according to various operation modes and an activation operation of the power amplifier, and furthermore, may supply power through various combinations of circuits. In particular, the supply modulating circuit according to one or more embodiments may operate the high-capacity PA (i.e., the PA3 530) by supplying a high voltage only with a low-capacity converter (i.e., the first and second supply modulators 320 and 330) through a switching operation. That is, the supply modulating circuit according to one or more embodiments may operate PAs having various required powers and/or high-capacity PAs through a combination of low-capacity converters without a separate high-capacity converter. Accordingly, the cost and circuit size for various supply modulations may be reduced.

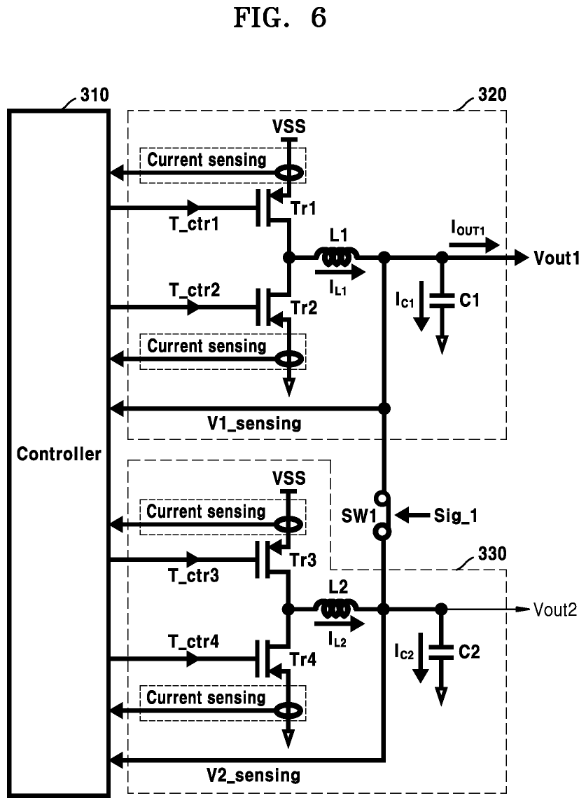

FIG. 6 is a circuit diagram illustrating a supply modulating circuit according to one or more embodiments.

Referring to FIGS. 5 and 6, the controller 310 may control generating of voltage of the first supply modulator 320 and the second supply modulator 330. The first supply modulator 320 may include a first transistor Tr1, a second transistor Tr2, a first inductor L1, and a first capacitor C1, and the second supply modulator 330 may include a third transistor Tr3, a fourth transistor Tr4, a second inductor L2, and a second capacitor C2. As described above, the first to fourth transistors Tr1 to Tr4 may be operated by applying a reference voltage Vss to the first supply modulator 320 and the second supply modulator 330.

The controller 310 may generate current by controlling operations of the first transistor Tr1 and the second transistor Tr2 through a first transistor control signal T_ctrl1 and a second transistor control signal T_ctrl2. As shown, the controller 310 may sense current generated from the first transistor Tr1 and the second transistor Tr2. As an example, a separate circuit may be additionally arranged for current sensing. Current generated from the transistors and flowing through the first inductor L1 may be referred to as a first inductor current I_{L1}, and based on the first inductor current I_{L1}, a first capacitor current I_{C1} and a first output current I_{OUT1} for charging and discharging the first capacitor C1 may be formed. A first output voltage Vout1 may be generated based on charging and discharging of the first capacitor C1. Also, as shown, the controller 310 may sense a voltage generated by the first supply modulator 320 through a separate circuit (V1_sensing). The controller 310 may control voltage generation of the first supply modulator 320 based on the current sensing and the voltage sensing.

In the same manner, the controller 310 may generate current by controlling the third transistor Tr3 and the fourth transistor Tr4 through the third transistor control signal T_ctrl3 and the fourth transistor control signal T_ctrl4, and as shown, the controller 310 may sense the generated current. Based on a second inductor current I_{L2} generated from the transistors and flowing through the second inductor L2, a second capacitor current I_{C2} for charging and discharging the second capacitor C2 may be formed. A second output voltage Vout2 may be generated based on the charging and discharging of the second capacitor C2, and as shown, the controller 310 may sense a voltage generated by the second supply modulator 330 through a separate circuit (V2_sensing). The controller 310 may control voltage generation of the second supply modulator 330 based on the current sensing and the voltage sensing.

In some embodiments, the controller 310 may control a multi-phase operation based on the voltage generation control described above. As an embodiment, the controller 310 may control the third operation mode (i.e., high-capacity output mode) described above with reference to FIG. 5 based on multi-phase control. In detail, in the case of the third operation mode, the first switch SW1 may be turned on and shorted based on the first switching signal Sig_1 as described above, and the controller 310 may detect a present state of the circuit through the current sensing and/or voltage sensing (V1_sensing, V2_sensing) and adjust the first transistor control signal T_ctrl1 to the fourth transistor control signal T_ctrl4, thereby controlling the first supply modulator 320 and the second supply modulator 330.

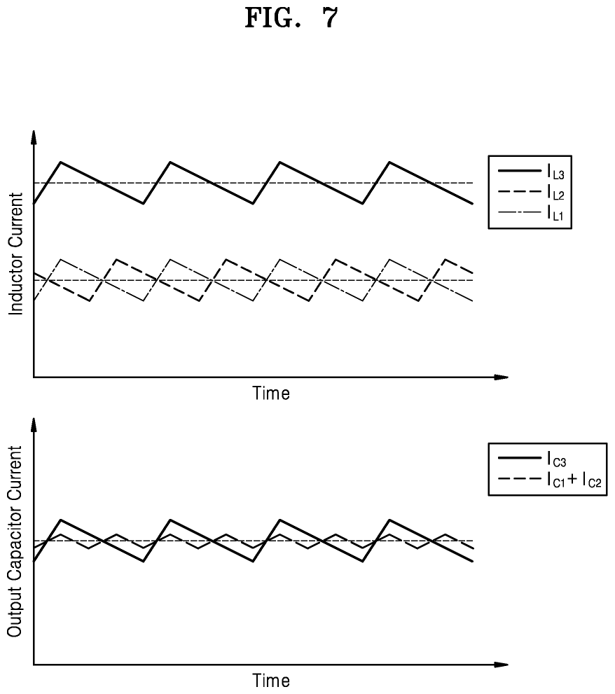

FIG. 7 is a graph illustrating characteristics of current measured in the supply modulating circuit of FIG. 6.

Referring to FIGS. 6 and 7, the controller 310 may control a multi-phase operation based on currents in the first supply modulator 320 and the second supply modulator 330. When performing high-capacity output using a high-capacity converter instead of a low-capacity converter, it is assumed that currents measured in an inductor and capacitor of the first supply modulator 320 are a third inductor current I_{L3} and a third capacitor current I_{C3}.

As shown in the graph, a current level of the third inductor current I_{L3} may be relatively high because a single high-capacity converter is used, and current levels of the first inductor current I_{L1} and the second inductor current I_{L2} may be relatively low. In particular, when a single high-capacity converter is used, an operation is performed based on only a single inductor current (i.e., the third inductor current I_{L3}), and thus, ripple characteristics appear with longer periods (i.e., larger current fluctuation) as shown. When a plurality of low-capacity converters according to an embodiment are used, the operation is performed based on the inductor currents (i.e., the first inductor current I_{L1} and the second inductor current I_{L2}), and thus, the ripple characteristics may appear crossed (i.e., with smaller current fluctuation). That is, when this characteristic is viewed based on a capacitor that generates an output voltage while being charged and discharged, as shown, the third capacitor current I_{C3} and the sum of the first capacitor current I_{C1} and the second capacitor current I_{C2} may be compared. As in the inductor current graph, each current flows based on the same switching frequency, but when observed based on the output capacitor(s), the supply modulating circuit according to an embodiment may reduce ripple characteristics as shown in the capacitor current graph. In this manner, the controller 310 may control the multi-phase operation for controlling the supply modulators including the low-capacity converters. That is, the supply modulating circuit according to the embodiment may reduce the ripple characteristics of the output voltage through multi-phase control.

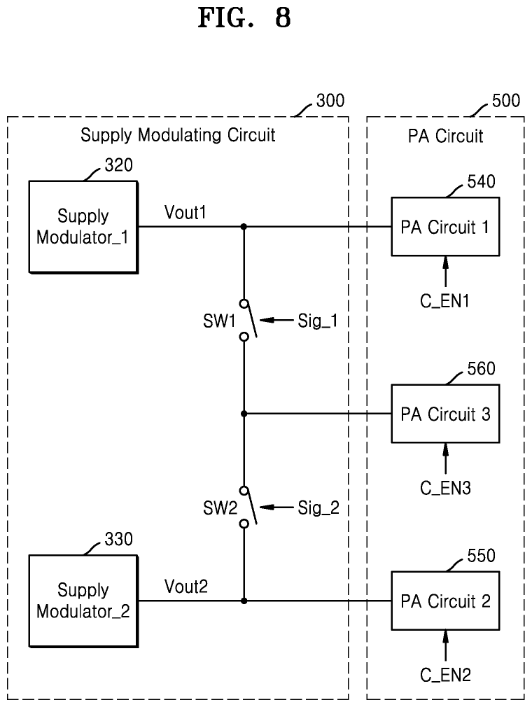

FIG. 8 is a diagram illustrating the supply modulating circuit 300 and the PA circuit 500 according to one or more embodiments.

Referring to FIGS. 3 and 8, the supply modulating circuit 300 may include the first supply modulator 320, the second supply modulator 330, the first switch SW1, and a second switch SW2, and the PA circuit 500 may include a first PA circuit (or a PA circuit 1) 540, a second PA circuit (or a PA circuit 2) 550, and a third PA circuit (or a PA circuit 3) 560. Hereinafter, the same descriptions as those given above with reference to FIG. 3 are omitted.

As shown, the PA circuit 1 540 may be disposed to correspond to the first supply modulator 320, and the PA circuit 2 550 may be disposed to correspond to the second supply modulator 330. In order to configure more diverse combinations, a separate output port connected to the PA circuit 3 560 may be configured as shown by locating the first switch SW1 and the second switch SW2.

The first switch SW1 and the second switch SW2 may perform turn-on/turn-off operations based on the first switching signal Sig_1 and a second switching signal Sig_2, respectively. As described above with reference to FIG. 3, the second switching signal Sig_2 may be provided from an external source, such as a modem or control circuit, or may be provided from a separate switch controller for controlling a switch in the supply modulating circuit 300.

The PA circuit 500 may include the PA circuits 1 to 3 540, 550, and 560. Each of the PA circuits 1 to 3 540, 550, and 560 may include at least one low-capacity PA and at least one high-capacity PA. The arrangement of low-capacity and/or high-capacity PAs may be implemented in various manners. The PA circuits 1 to 3 540, 550, and 560 may receive an output voltage from the supply modulating circuit 300 based on first to third circuit enable signals C_EN1, C_EN2, and C_EN3, respectively, and perform an amplification operation. For example, the PA circuit 1 540 may receive the first circuit enable signal C_EN1 determined according to an operation mode. When the PA circuit 1 540 is activated according to the first circuit enable signal C_EN1, the PA circuit 1 540 may amplify an RF input signal based on a voltage provided from the supply modulating circuit 300 to generate an RF output signal. In the same manner, when the PA circuit 2 550 and the PA circuit 3 560 are activated according to the second circuit enable signal C_EN2 and the third circuit enable signal C_EN3, respectively, the PA circuit 2 550 and the PA circuit 3 560 may generate output signals based on the voltage provided from the supply modulating circuit 300.

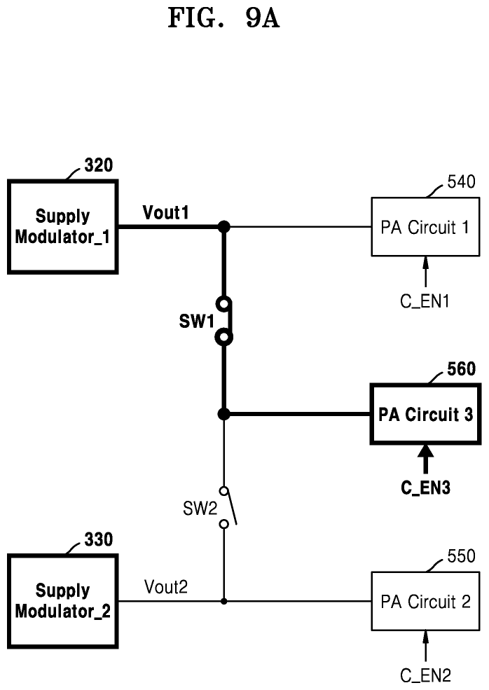

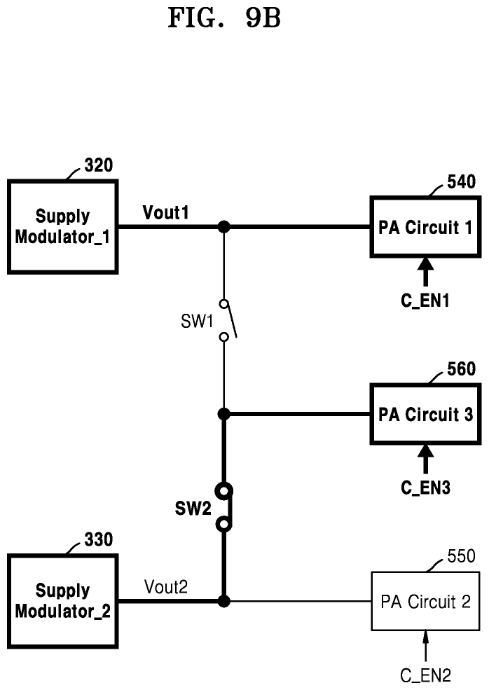

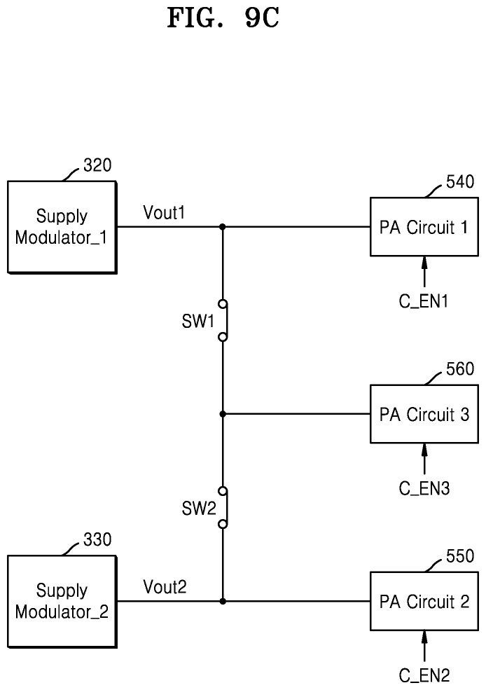

FIGS. 9A to 9C are diagrams illustrating circuit operations according to operation modes of the supply modulating circuit 300 and the PA circuit 500 according to embodiments.

Referring to FIG. 9A, the supply modulating circuit 300 and the PA circuit 500 may operate according to a first operation mode. The first operation mode may be referred to as a low-capacity single output mode.

In some embodiments, in the case of the first operation mode, as shown, the first switch SW1 may be turned on and shorted based on a corresponding switching signal, and the second switch SW2 may be turned off and opened based on a corresponding switching signal. The first voltage Vout1 output from the first supply modulator 320 may be applied to the PA circuit 1 540 and the PA circuit 3 560. Here, in the first operation mode, the PA circuit 3 560 may be activated based on the third circuit enable signal C_EN3, and accordingly, the PA circuit 3 560 may output an RF output signal based on the first voltage Vout1. The PA circuit 1 540 may be deactivated based on the first circuit enable signal C_EN1 and may thus not operate even when the first voltage Vout1 is applied (that is, the PA circuit 1 540 may be in a disable state). Similarly, the PA circuit 2 550 may be deactivated based on the second circuit enable signal C_EN2 and may not operate. That is, only the PA circuit 3 560 may generate an RF output signal in the first operation mode. For example, a low-capacity PA in the PA circuit 3 560 may be activated to generate the RF output signal.

In some embodiments, in the case of the first operation mode, contrary to the embodiment described above, the first switch SW1 may be turned off and opened based on a corresponding switching signal and the second switch SW2 may be turned on and shorted based on a corresponding switching signal. Accordingly, the PA circuit 3 560 may output an RF output signal based on the second voltage Vout2.

In some embodiments, similar to the case in FIGS. 4A and 4B, the first operation mode may be performed through one of the PA circuit 1 540 and the PA circuit 2 550. That is, both the first switch SW1 and the second switch SW2 may be turned off and opened based on the corresponding switching signals. Only one of the PA circuit 1 540 and the PA circuit 2 550 may be activated to generate an RF output signal.

Referring to FIG. 9B, the supply modulating circuit 300 and the PA circuit 500 may operate according to the second operation mode. The second operation mode may be referred to as a low-capacity simultaneous output mode.

In some embodiments, in the case of the second operation mode, as shown, the first switch SW1 may be turned off and opened based on a corresponding switching signal, and the second switch SW2 may be turned on and shorted based on a corresponding switching signal. In this case, the PA circuit 1 540 may be activated based on the first circuit enable signal C_EN1 and output an RF output signal based on the first voltage Vout1. In addition, the PA circuit 3 560 may be activated based on the third circuit enable signal C_EN3 and output an RF output signal based on the second voltage Vout2. The PA circuit 2 550 may be deactivated based on the second circuit enable signal C_EN2 and may not operate (i.e., the PA circuit 2 550 may be in a disable state). For example, low-capacity PAs in the PA circuit 1 540 and the PA circuit 3 560 may be activated. That is, in the second operation mode, both the PA circuit 1 540 and the PA circuit 3 560 may generate RF output signals based on the low-capacity PAs.

In the case of the second operation mode, contrary to the embodiment described above, the first switch SW1 may be turned on and shorted based on a corresponding switching signal, and the second switch SW2 may be turned off and opened based on a corresponding switching signal. In this case, the PA circuit 2 550 may generate an RF output signal based on the second voltage Vout2 and the PA circuit 3 560 may generate an RF output signal based on the first voltage Vout1.

Referring to FIG. 9C, the supply modulating circuit 300 and the PA circuit 500 may operate according to the third operation mode. The third operation mode may be referred to as a high-capacity output mode.

In some embodiments, in the case of the third operation mode, both the first switch SW1 and the second switch SW2 may be turned on and shorted based on switching signals. Therefore, both the first voltage Vout1 and the second voltage Vout2 output from the first supply modulator 320 and the second supply modulator 330 may be applied to the PA circuits 1 to 3 540, 550, and 560. Here, one of the PA circuits 1 to 3 540, 550, and 560 may be activated based on a corresponding circuit enable signal and may generate an RF output signal based on the first voltage Vout1 and the second voltage Vout2. For example, a high-capacity PA in an activated PA circuit may be activated to generate an RF output signal. PA circuits other than the activated PA circuit may be deactivated based on a corresponding circuit enable signal and may thus not operate even when voltage is applied thereto (i.e., may be in a disable state). That is, in the third operation mode, only one PA circuit may generate an RF output signal.

That is, the supply modulating circuit according to one or more embodiments may supply power through various combinations of circuits by additionally configuring a port through which a voltage is output through switches. In particular, the supply modulating circuit according to one or more embodiments may operate PAs having various required powers and/or high-capacity PAs through a combination of low-capacity converters without a separate high-capacity converter. Accordingly, the cost and circuit size for various power supply modulations may be reduced.

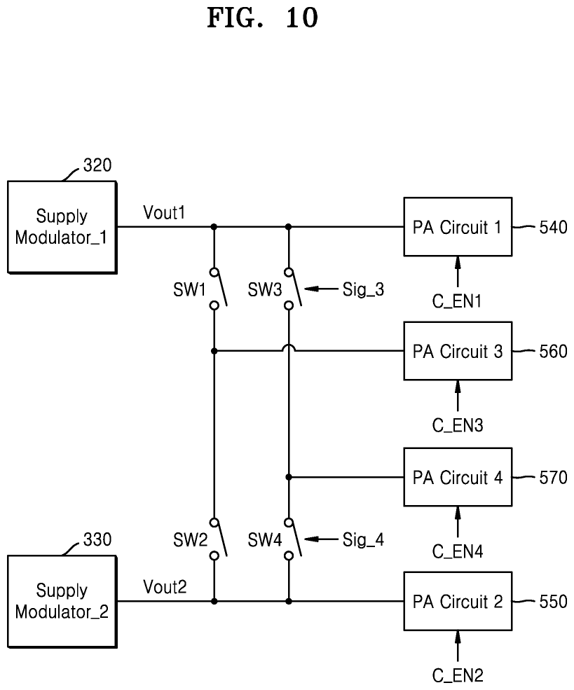

FIG. 10 is a diagram illustrating the supply modulating circuit 300 and the PA circuit 500 according to one or more embodiments.

Referring to FIGS. 8 and 10, the supply modulating circuit 300 may further include a third switch SW3 and a fourth switch SW4, and the PA circuit 500 may further include a fourth PA circuit (or a PA circuit 4) 570. Hereinafter, the same descriptions as those given above with reference to FIG. 8 are omitted.

The third and fourth switches SW3 and SW4 may perform turn-on/turn-off operations based on third and fourth switching signals Sig_3 and Sig_4, respectively. As described above with reference to FIG. 8, the third and fourth switching signals Sig_3 and Sig_4 may be provided from an external source, such as a modem or a control circuit, or may be provided from a separate switch controller for controlling a switch in the supply modulating circuit 300.

The PA circuit 500 may further include the PA circuit 4 570. The PA circuit 4 570 may include at least one low-capacity PA and at least one high-capacity PA, and the arrangement of the amplifiers may be implemented in various manners. The PA circuit 4 570 may receive an output voltage from the supply modulating circuit 300 based on a fourth circuit enable signal C_EN4 determined according to an operation mode and perform an amplification operation to generate an RF output signal.

That is, in the supply modulating circuit according to an embodiment, in order to more diversify circuit combinations for supplying voltage, a separate output port connected to the PA circuit 4 570 as shown may be further configured by additionally arranging switches.

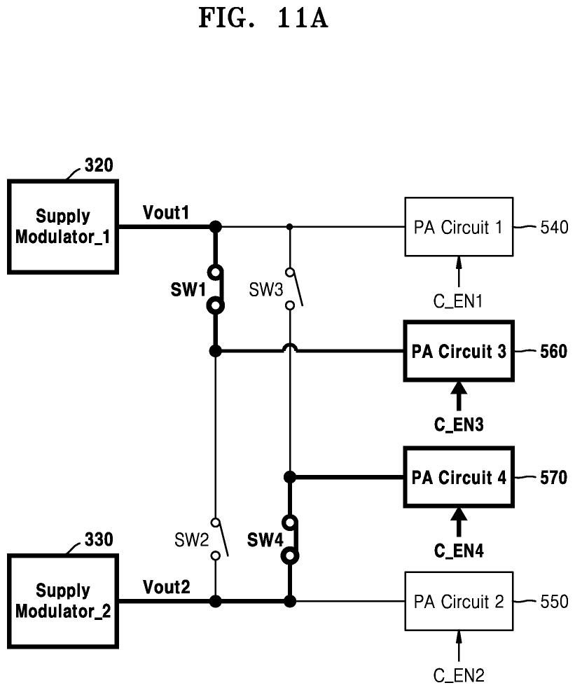

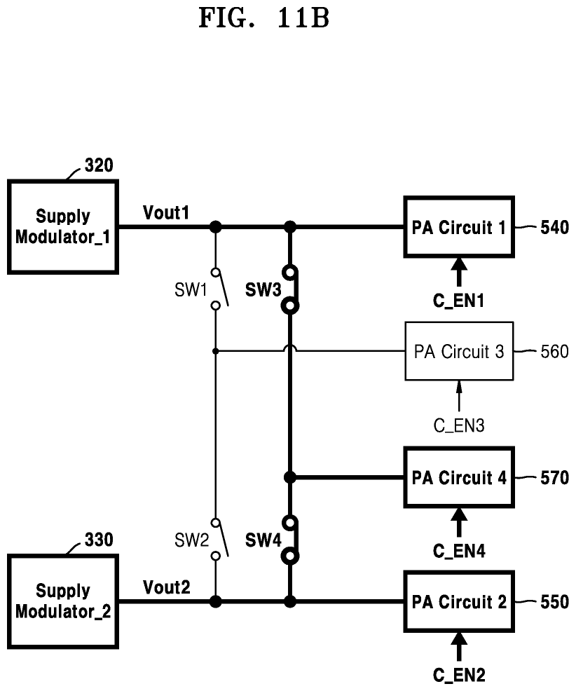

FIGS. 11A and 11B are diagrams illustrating circuit operations according to operation modes of the supply modulating circuit 300 and the PA circuit 500 according to embodiments.

Referring to FIG. 11A, the supply modulating circuit 300 and the PA circuit 500 may operate according to the second operation mode. The second operation mode may be referred to as a low-capacity simultaneous output mode. In relation to the second operation mode, the same descriptions as those given above with reference to FIG. 9A are omitted. That is, in this drawing, a case in which simultaneous output is performed by including the PA circuit 4 570 is described.

In some embodiments, in the case of the second operation mode, as shown, the first switch SW1 and the fourth switch SW4 may be turned on and shorted, and the second switch SW2 and the third switch SW3 may be turned off and opened. In this case, the PA circuit 3 560 and the PA circuit 4 570 may be activated based on the third circuit enable signal C_EN3 and the fourth circuit enable signal C_EN4, respectively. The PA circuit 1 540 and the PA circuit 2 550 may be deactivated and may not operate. For example, the low-capacity PAs in the third PA circuit 3 560 and the PA circuit 4 570 may be activated to output an RF output signal based on the first voltage Vout1 and the second voltage Vout2.

In the case of the second operation mode, contrary to the embodiment described above, the first switch SW1 and the fourth switch SW4 may be turned off and opened, and the second switch SW2 and the third switch SW3 may be turned on and shorted. In this case, after being activated, the third PA circuit 3 560 and the PA circuit 4 570 may output RF output signals based on the second voltage Vout2 and the first voltage Vout1, respectively.

That is, the supply modulating circuit according to an embodiment may activate the PA circuits to receive the first voltage Vout1 and the second voltage Vout2, respectively, and perform the second operation mode through an appropriate switching operation.

Referring to FIG. 11B, the supply modulating circuit 300 and the PA circuit 500 may operate according to the third operation mode. The third operation mode may be referred to as a high-capacity output mode.

In some embodiments, in the case of the third operation mode, both the third switch SW3 and the fourth switch SW4 may be turned on and shorted based on switching signals. Therefore, both the first voltage Vout1 and the second voltage Vout2 output from the first supply modulator 320 and the second supply modulator 330 may be applied to the first, second and fourth PA circuits 540, 550, and 570. One of the first, second, and fourth PA circuits 540, 550, and 570 may be activated based on a corresponding circuit enable signal and may generate an RF output signal based on the first voltage Vout1 and the second voltage Vout2. For example, a high-capacity PA in the activated PA circuit may be activated to generate an RF output signal. PA circuits other than the activated PA circuit may be deactivated based on a corresponding circuit enable signal and may thus not operate even when voltage is applied thereto (i.e., may be in a disable state). That is, in the third operation mode, only one PA circuit may generate an RF output signal.

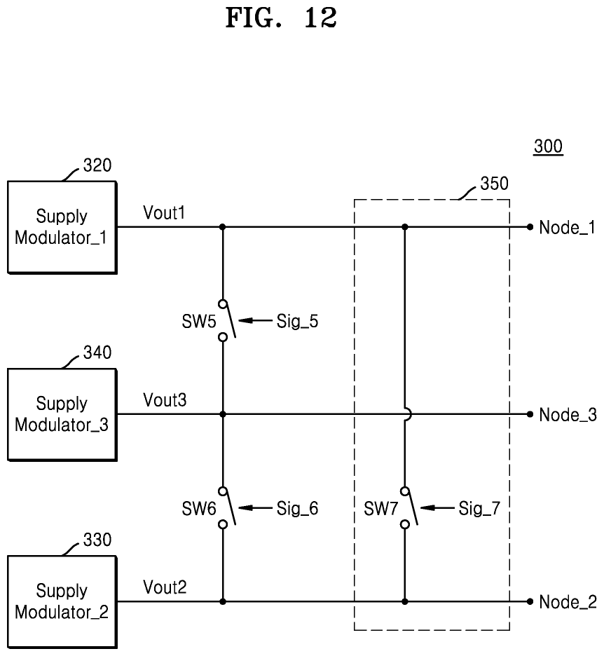

FIG. 12 is a circuit diagram illustrating the supply modulating circuit 300 according to an embodiment.

Referring to FIGS. 8 and 12, the supply modulating circuit 300 may include the first supply modulator 320, the second supply modulator 330, a fifth switch SW5, a sixth switch SW6, a first output terminal Node_1, a second output terminal Node_2, and a third output terminal Node_3. The supply modulating circuit 300 may configure various circuit combinations through an internal switching operation and output voltages through the first to third output terminals Node_1 to Node_3. Hereinafter, the same descriptions as those given above with reference to FIG. 8 are omitted.

The fifth switch SW5 and the sixth switch SW6 may perform turn-on/turn-off operations based on fifth and sixth switching signals Sig_5 and Sig_6, respectively. The fifth and sixth switching signals Sig_5 and Sig_6 may be provided from an external source, such as a modem or a control circuit, or may be provided from a separate switch controller for controlling a switch in the supply modulating circuit 300.

In some embodiments, the supply modulating circuit 300 may further include a third supply modulator 340. The third supply modulator 340 may output a third voltage Vout3 and may be a modulator using a relatively small capacity converter (e.g., a DC-DC converter). That is, the supply modulating circuit 300 may provide voltage through up to 3 channels, unlike the examples of up to 2 channels described above. As described above with reference to the above drawings, the first to third operation modes may be performed based on various switching operations.

In some embodiments, the supply modulating circuit 300 may operate according to a fourth operation mode, which may be referred to as a high-capacity and low-capacity simultaneous output mode. For example, the fifth switch SW1 may be turned off and opened, and the sixth switch SW6 may be turned on and shorted. In this case, voltage may be output through one of the first output terminal Node_1, the second output terminal Node_2, and the third output terminal Node_3. The first output terminal Node_1 may output the first voltage Vout1, while one of the second output terminal Node_2 and the third output terminal Node_3 may output both the second voltage Vout2 and the third output voltage Vout3, and thus provide relatively high voltages to a PA circuit.

In some embodiments, the supply modulating circuit 300 may further include a switching circuit 350. The switching circuit 350 may include a seventh switch SW7 operating according to a seventh switching signal Sig_7. Similarly, the supply modulating circuit 300 may perform the first to fourth operation modes based on various switching operations including the seventh switch SW7 as described above with reference to the above drawings.

That is, the supply modulating circuit according to one or more embodiments may configure more diverse circuit combinations by adding channels by arranging supply modulators and may provide a more diverse range of output voltages due to the increased number of channels. Furthermore, the supply modulating circuit according to the present embodiment may provide more diverse operation modes because the number of output terminals that may be simultaneously driven also increases. In addition, more diverse circuit combinations may be configured by adding a switching circuit connecting the output terminals to each other.

While example embodiments have been particularly shown and described, it will be understood that various changes in form and details may be made therein without departing from the spirit and scope of the following claims.

What is claimed is:

1. A communication circuit comprising:
a first supply modulator configured to provide a first supply voltage;
a second supply modulator configured to provide a second supply voltage;
a switch configured to switch between output terminals of the first supply modulator and the second supply modulator;
a first power amplifier configured to receive the first supply voltage and amplify a first input signal;
a second power amplifier configured to receive the second supply voltage and amplify a second input signal;
a third power amplifier configured to use third power higher than first power of the first power amplifier and second power of the second power amplifier, receive the first supply voltage and the second supply voltage, and amplify a third input signal; and
a control circuit configured to control a switching operation of the switch based on an operation mode and activate at least one of the first power amplifier, the second power amplifier, and the third power amplifier based on the operation mode.

2. The communication circuit of claim 1, wherein the control circuit is further configured to, based on the operation mode being a first operation mode, turn off the switch and activate one of the first power amplifier and the second power amplifier.

3. The communication circuit of claim 1, wherein the control circuit is further configured to, based on the operation mode being a second operation mode, turn off the switch and activate the first power amplifier and the second power amplifier.

4. The communication circuit of claim 1, wherein the control circuit is further configured to, based on the operation mode being a third operation mode, turn on the switch and activate the third power amplifier.

5. The communication circuit of claim 1, wherein at least one supply modulator among the first supply modulator and the second supply modulator comprises at least one of:
i) an envelope tracker configured to adjust a voltage level of a corresponding supply voltage based on an envelope signal received from the control circuit; and
ii) an average power tracker configured to adjust the voltage level of the corresponding supply voltage based on a period average power of an input signal received from the control circuit, and
wherein the at least one supply modulator is configured to adjust the voltage level of the corresponding supply voltage using at least one of the envelope tracker and the average power tracker.

6. The communication circuit of claim 1, further comprising a controller configured to control a phase of current in at least one of the first supply modulator and the second supply modulator.

7. The communication circuit of claim 1, further comprising a controller configured to control a phase of current of the first supply modulator to be different from a phase of current of the second supply modulator based on the operation mode.

8. A communication circuit comprising:
a first power amplifier circuit;
a first supply modulator configured to provide a first supply voltage to the first power amplifier circuit;
a second power amplifier circuit;
a second supply modulator configured to provide a second supply voltage to the second power amplifier circuit;
a third power amplifier circuit;
a first switch having one end connected to an input terminal of the first power amplifier circuit and another end connected to an input terminal of the third power amplifier circuit;
a second switch having one end connected to an input terminal of the second power amplifier circuit and another end connected to the input terminal of the third power amplifier circuit; and
a control circuit configured to control the first switch and the second switch upon receiving a control signal based on an operation mode,
wherein the input terminal of the third power amplifier circuit is connected to at least one of the first supply modulator and the second supply modulator.

9. The communication circuit of claim 8, wherein, based on the operation mode being a first operation mode, the control circuit is further configured to turn on one of the first switch and the second switch, and active the third power amplifier circuit.

10. The communication circuit of claim 8, wherein, based on the operation mode being a second operation mode, the control circuit is further configured to turn on one of the first switch and the second switch, and activate a power amplifier circuit, among the first power amplifier circuit and the second power amplifier circuit, corresponding to a switch in an off state among the first switch and the second switch, and the third power amplifier circuit.

11. The communication circuit of claim 8, wherein the control circuit is configured to, based on the operation mode being a third operation mode, turn on the first switch and the second switch, and activate one of the first power amplifier circuit, the second power amplifier circuit and the third power amplifier circuit.

12. The communication circuit of claim 8, further comprising:
a third switch having one end connected to the input terminal of the first power amplifier circuit and another end connected to input terminal of a fourth power amplifier circuit; and
a fourth switch having one end connected to the input terminal of the second power amplifier circuit and another end connected to the input terminal of the fourth power amplifier circuit,
wherein the input terminal of the fourth power amplifier circuit is connected to at least one of the first supply modulator and the second supply modulator by controlling the third switch and the fourth switch upon receiving the control signal according to the operation mode.

13. The communication circuit of claim 12, wherein the control circuit is further configured to, based on the operation mode being a first operation mode:
turn off the first switch and the second switch,
turn on one of the third switch and the fourth switch, and
activate the fourth power amplifier circuit.

14. The communication circuit of claim 12, wherein the control circuit is further configured to, based on the operation mode being a second operation mode:
turn off the first switch and the second switch,
turn on one of the third switch and the fourth switch,
activate a power amplifier circuit, among the first power amplifier circuit and the second power amplifier circuit, corresponding to the third switch being in an off state or the fourth switch being in the off state, and
activate the fourth power amplifier circuit.

15. The communication circuit of claim 12, wherein, when the operation mode is a second operation mode, the control circuit is further configured to:
turn on one of the first switch and the second switch,
turn on one of the third switch and the fourth switch, and
activate the third power amplifier circuit and the fourth power amplifier circuit.

16. The communication circuit of claim 12, wherein the control circuit is further configured to, based on the operation mode being a third operation mode:
turn on the third switch and the fourth switch, and
activate one of the first power amplifier circuit, the second power amplifier circuit, and the fourth power amplifier circuit.

17. A supply modulating circuit comprising:
a first supply modulator configured to output a first supply voltage through a first output terminal;
a second supply modulator configured to output a second supply voltage through a second output terminal;
a first switch having one end connected to the first output terminal and another end connected to a third output terminal, the first switch being configured to switch between the first output terminal and the third output terminal; and
a second switch having one end connected to the second output terminal and another end connected to the third output terminal, the second switch being configured to switch between the first output terminal and the third output terminal.

18. The supply modulating circuit of claim 17, further comprising a third supply modulator configured to output a third supply voltage through the third output terminal.

19. The supply modulating circuit of claim 17, further comprising a control circuit configured to output a control signal for switching at least one of the first switch and the second switch.

20. The supply modulating circuit of claim 18, further comprising a third switch having one end connected to the first output terminal and another end connected to the second output terminal, the third switch being configured to switch between the first output terminal and the second output terminal.
